(19) United States
(12) Patent Application Publication
(10) Pub. No.: US 2017/0353035 A1
(43) Pub. Date: Dec. 7, 2017

(54) ISLANDING DETECTION METHOD BASED ON TORQUE OSCILLATIONS OF INTERNAL COMBUSTION ENGINES

(71) Applicant: United Technologies Corporation, Farmington, CT (US)

(72) Inventors: Virgilio Valdivia Guerrero, Almeria (ES); Francisco José González Espín, Donnybrook (IE); Raymond Francis Foley, Carraig na bhFear (IE); Nicolás Chialin Prieto Chang, Aachen (DE)

(21) Appl. No.: 15/535,460

(22) PCT Filed: Dec. 17, 2014
(86) PCT No.: PCT/US14/70805

§ 371 Date: Jun. 13, 2017

(51) Int. Cl. H02J 3/38; F01D 15/10; F02B 63/04; G01R 31/34

(52) U.S. Cl. CPC H02J 3/381; G01R 31/343; F01D 15/10; F02B 63/04; H02J 2003/388

(57) ABSTRACT

An assembly for detecting a grid condition according to an exemplary aspect of the present disclosure includes, among other things, a controller that determines an electrical variation of an electrical parameter, the electrical variation relating to a mechanical torque oscillation of a power generation device, and determines that the power generation device should be disconnected from the power grid if the electrical variation meets a preselected criterion. A method of detecting a grid event is also disclosed.

### BACKGROUND

This application relates to power generation and, more particularly, to controlling distributed power generation devices electrically connected to a power grid.

Some power grids are electrically coupled to at least one distributed power generation device that provides power to the power grid over an alternating current electrical bus. The power grid is typically coupled to a main or utility service power source that provides power to at least one external load. There are challenges associated with controlling when the distributed power generation device delivers power based on operating conditions of the main power source or the bus.

### SUMMARY

An assembly for detecting a grid condition according to the example of the present disclosure includes at least one sensor operable to detect an electrical parameter of a portion of a power grid. A controller that receives information from the at least one sensor determines an electrical variation of the electrical parameter based on the information. The electrical variation relates to a mechanical torque oscillation of a power generation device, and determines that the power generation device should be disconnected from the power grid if the electrical variation meets a preselected criterion.

In a further embodiment of any of the foregoing embodiments, the power generation device is one of an internal combustion engine, a turbine, and a heating, ventilation and air condition (HVAC) system.

In a further embodiment of any of the foregoing embodiments, the power generation device is an internal combustion engine. The electrical variation occurs at an electrical frequency relating to a mechanical torque oscillation frequency. The mechanical torque oscillation frequency is based on at least one of a piston quantity and a rotational speed of the internal combustion engine.

In a further embodiment of any of the foregoing embodiments, the electrical parameter is at least one of an instantaneous voltage, an instantaneous current, an instantaneous power and an instantaneous impedance on the portion of the power grid.

In a further embodiment of any of the foregoing embodiments, the electrical variation corresponds to an instantaneous change in mechanical torque produced by the power generation device.

In a further embodiment of any of the foregoing embodiments, the electrical variation relates to an instantaneous change in configuration of at least a portion of the power grid.

In a further embodiment of any of the foregoing embodiments, the preselected criterion corresponds to a magnitude of the electrical parameter.

A generator assembly according to an example of the present disclosure includes a mechanical power generation device having an output shaft and an electrical generator coupled to the output shaft. The electrical generator has output terminals configured to couple the electrical generator to a portion of a power grid. A controller determines an electrical variation in an electrical parameter of the portion of the power grid that relates to a mechanical torque oscillation of the mechanical power generation device at the output shaft, and determines that at least one of the mechanical power generation device and the electrical generator should be disconnected from the portion of the power grid in response to the electrical variation.

In a further embodiment of any of the foregoing embodiments, the controller is operable to change at least one of the mechanical power generation device and the electrical generator from a first operating state to a second operating state in response to the electrical variation.

In a further embodiment of any of the foregoing embodiments, the mechanical power generation device is an internal combustion engine. The electrical variation occurs at an electrical frequency relating to a mechanical torque oscillation frequency. The mechanical torque oscillation frequency is based on at least one of a piston quantity and a rotational speed of the internal combustion engine.

In a further embodiment of any of the foregoing embodiments, the mechanical power generation device is a turbine. The electrical variation occurs at an electrical frequency relating to a mechanical torque oscillation frequency. The mechanical torque oscillation frequency is based on a quantity of rotor blades of the turbine and a rotational speed of the turbine.

In a further embodiment of any of the foregoing embodiments, the controller is operable to filter the electrical parameter based on a present rotational speed of the output shaft.

In a further embodiment of any of the foregoing embodiments, the electrical variation corresponds to an impedance of the power grid.

In a further embodiment of any of the foregoing embodiments, the portion of the power grid is a microgrid and a main grid, and the controller is operable to determine that the microgrid should be disconnected from the main grid in response to the electrical variation.

A method of detecting a grid event according to an example of the present disclosure includes determining that an electrical variation of a portion of a power grid meets a preselected criterion. The electrical variation relates to a mechanical torque oscillation of a power generation device. The method includes disconnecting the power generation device from the portion of the power grid if the electrical variation meets the preselected criterion.

A further embodiment of any of the foregoing embodiments includes filtering the electrical variation at an electrical frequency relating to a mechanical torque oscillation frequency of the power generation device, the mechanical torque oscillation occurring at the mechanical torque oscillation frequency.

In a further embodiment of any of the foregoing embodiments, the power generation device is an internal combustion engine coupled to an electrical generator via an output shaft, and the mechanical torque oscillation frequency is estimated based on at least one of a piston quantity and a rotational speed of an output shaft of the internal combustion engine.

In a further embodiment of any of the foregoing embodiments, the electrical frequency is a first frequency of oscillation and a second frequency of oscillation. The second frequency of oscillation relates to a mechanical torque oscillation of a second power generation device. The first frequency of oscillation and the second frequency of oscillation are separate and distinct.

In a further embodiment of any of the foregoing embodiments, the electrical variation corresponds to an instantaneous change in mechanical torque produced by the power generation device.

In a further embodiment of any of the foregoing embodiments, the electrical parameter is at least one of an instantaneous voltage, an instantaneous current, an instantaneous power, and an instantaneous impedance on the portion of the power grid.

The various features and advantages of disclosed embodiments will become apparent to those skilled in the art from the following detailed description. The drawings that accompany the detailed description can be briefly described as follows.

### BRIEF DESCRIPTION OF THE DRAWINGS

FIG. 1 schematically illustrates an electrical grid.

FIG. 2 graphically illustrates a mechanical torque profile for an example power generation device.

FIG. 3A illustrates a method of detecting a grid condition.

FIG. 3B graphically illustrates a voltage profile for an electrical bus of the electrical grid of FIG. 1.

FIG. 3C graphically illustrates a plot of voltage versus frequency for components of the electrical grid of FIG. 1.

FIG. 3D graphically illustrates a plot of voltage over time at a given frequency.

FIG. 4A illustrates a second embodiment of a method of detecting a grid condition.

FIG. 4B graphically illustrates a plot of voltages over time at a given frequency.

### DETAILED DESCRIPTION

The disclosed embodiments provide the ability to identify an “islanding” condition in which power generation equipment remotely located from a main grid should be disconnected from the main grid by using electrical parameter variations in an electrical grid. The electrical parameter variations are monitored at an electrical frequency or frequencies relating to a frequency of mechanical torque oscillations in the power generation equipment. Monitoring one or more parameters at such a frequency allows any parameter changes to be used to infer changes to the electrical grid configuration due to an “islanding” condition, which is discussed in more detail below. The variations in the electrical parameters are associated with changes to the electrical grid. The need to disconnect the power generation equipment from the main grid becomes apparent when at least one selected criterion is met.

In this disclosure, like reference numerals designate like elements where appropriate and reference numerals with the addition of one-hundred or multiples thereof designate modified elements that are understood to incorporate the same features and benefits of the corresponding original elements.

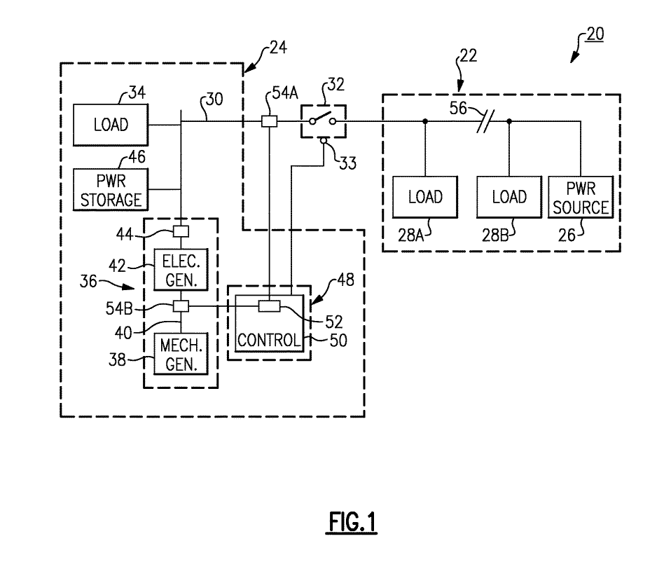

FIG. 1 schematically illustrates an electrical grid 20, including a main grid 22 and a microgrid 24. The main grid 22 has an external power source 26, provided by a utility power service, for example. In some examples, the external power source 26 is a hydroelectric or nuclear power generation source, although other power sources are contemplated with the teachings of this disclosure. The main grid 22 has one or more associated external loads 28, such as external loads 28_{A} and 28_{B}, which may be a variety of different power consumption devices such as household appliances, or industrial and commercial electrical devices. In some examples, the microgrid 24 includes electrical storage and is coupled to other power distribution networks such as gas or water.

In some examples, the microgrid 24 is electrically coupled to the main grid 22 via an electrical bus 30. In some examples, the electrical bus 30 is a three-phase electrical bus configured to carry alternating current (AC) between various power generation and consumption devices electrically coupled to the main grid 22 and the microgrid 24. In some examples, power is provided on the electrical bus 30 at a fundamental frequency of approximately 50 hertz (Hz), and in other examples at approximately 60 Hz.

In this example, the electrical bus 30 is electrically coupled to the main grid 22 by at least one synchronous device 32 such as a circuit breaker, for example. The synchronous device 32 is operable to disconnect or electrically isolate the microgrid 24 from the main grid 22 in response to receiving a command at a signal interface 33. In some examples, the microgrid 24 includes at least one local load device 34 operable to consume power provided on the electrical bus 30. The local load device 34 includes commercial and/or industrial equipment, for example.

The microgrid 24 includes at least one generator assembly 36 electrically coupled to the electrical bus 30 to provide power for consumption by the local load devices 34 and/or the external loads 28. In some examples, the microgrid 36 includes two or more generator assemblies 36. The at least one generator assembly 36 is operable to provide sufficient power to the local load devices 34 independent of the external power source 26 of the main grid 22, for example. In another example, the microgrid 24 is configured to disconnect one or more of the local load devices 34 if the at least one generator assembly 36 does not provide sufficient power to the microgrid 24 when the external power source 26 is disconnected from the electrical bus 30. In other examples, the at least one generator assembly 36 selectively provides power to the one or more external loads 28 rather than to loads within a microgrid. In some examples, other power sources are also coupled to the microgrid 24.

In this example, the generator assembly 36 includes a mechanical power generation device 38 having an output shaft 40. In some examples, the mechanical power generation device 38 is either a two stroke or four stroke internal combustion engine having one or more pistons and is configured to rotate or otherwise move the output shaft 40. The mechanical power generation device 38 generates mechanical torque at a torque oscillation frequency (ω₁) to characterize a mechanical torque profile. The torque oscillation frequency (ω₁) is dependent on at least one of a piston quantity, a number of strokes, and a rotational speed of the mechanical power generation device 38 measured at the output shaft 40.

The torque oscillation frequency (ω₁) of the mechanical power generation device 38 can be defined in at least one of two ways as follows:

ω₁=ωₙ*(c/2) Equation 1:

ω₁=ωₙ*c Equation 2:

where c is the number of cylinders of the mechanical power generation device 38, and where ωₙ is a rotational speed of the output shaft 40 of the mechanical power generation device 38. In some examples, the variable (c) corresponds to a quantity of cylinders or pistons, for example, for engine combustion cycles in which each piston fires at a different instance in time. In other examples, the variable (c) corresponds to a quantity of pairs of cylinders or pistons for engine combustion cycles in which pistons fire pairwise. In some examples, the torque oscillation frequency (ω₁) and the rotational speed (ωₙ) are measured in radians per second, although other frequency units such as revolutions per minute (RPM) are contemplated. Equation 1 corresponds to a four stroke engine, and Equation 2 corresponds to a two stroke engine. The torque oscillation frequency (ω₁) relates to an electrical frequency of oscillation (f_{T}) of an electrical waveform at which mechanical torque oscillations will be reflected as changes in voltage or current, for example, and which is described in more detail below. In this example embodiment, changes in configuration to portions of the electrical grid 20 can be inferred from changes to the electrical waveform(s) at the electrical frequency of oscillation (f_{T}), even though the torque oscillation frequency (ω₁) is not measured directly during operation of the mechanical power generation device 38. Inferring the torque oscillation frequency (ω₁) can simplify the complexity of the system by foregoing the need to directly measure the torque oscillations on the output shaft 40 during operation. Although a combustion engine is provided in this example, other mechanical power generation devices are contemplated with the teachings of this disclosure, including wind turbines, hydro turbines and heating, ventilation and air condition (HVAC) systems, and any of the power storage devices discussed in this disclosure, for example. It should be appreciated that other units corresponding to the variable c in Equations 1 and 2 are contemplated, such as a number of rotor blades of a wind or hydro turbine, for example.

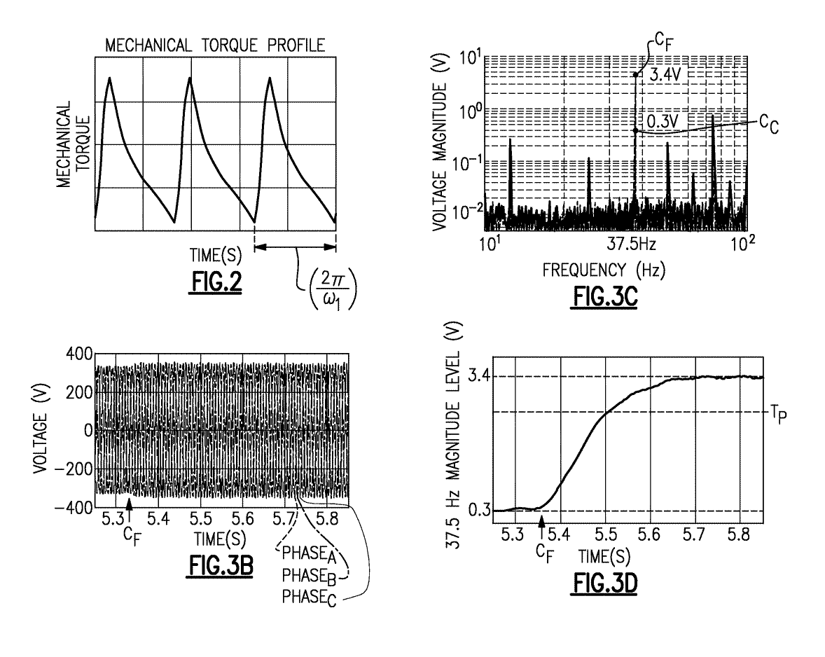

The rotational speed and torque generated by the mechanical power generation device 38 can vary during different operating conditions. These variations may also affect the electrical frequency of the power generation device 38, which in a weak grid, might also affect the frequency of the grid. Variation of grid frequency is typically limited to less than +/−5%, for example, although other variations are contemplated and can be accounted for utilizing the techniques of this description. In one example, the mechanical power generation device 38 has three pistons and a rotational speed of approximately 1500 RPMs during steady state operation, in which the torque oscillation frequency (ω₁) is equal to approximately 235.6 radian per second (rad/s) (which is approximately 37.5 Hz), and is characterized by a mechanical torque profile illustrated in FIG. 2 with corresponding time interval (2π/ω₁).

The generator assembly 36 includes an electrical generator 42 mechanically coupled to the output shaft 40 to convert mechanical energy provided by the mechanical power generation device 38 via the output shaft 40 into electrical energy to be provided on a power supply line. In one example, the electrical generator 42 is a wound-field generator. Other generator configurations are contemplated depending on the needs of a particular situation. One or more output terminals 44 of the electrical generator 42 are electrically coupled to the electrical bus 30.

In some examples, the microgrid 24 includes one or more power sources and/or storage devices operating in parallel with the at least one generator assembly 36 to provide power to the local load devices 34 and/or the external loads 28. In one example, the microgrid 24 has one or more power storage devices 46 coupled to the electrical bus 30. The power storage devices 46 are operable to selectively store power provided by the generator assembly 36 and/or the external power source 26 provided by the utility power service to the main grid 22, which in some examples is selectively provided to the local load devices 34 and external loads 28 coupled to the electrical bus 30. Other power sources coupled to the microgrid 24 are contemplated, including photovoltaic (PV) systems comprised of one or more solar panels, one or more wind turbines, and one or more steam turbines, for example.

A control assembly 48 is electrically coupled to the various components of the main grid 22 and/or microgrid 24. The example control assembly 48 is configured to provide various measurements, computations and control functions utilizing at least one controller 50. The controller 50 is a single board processor or another logic device, for example, and includes a sensor interface 52 for electrical communication with one or more sensors 54. The sensors 54 are positioned at any number of locations such as at sensor 54_{A} and 54_{B}. Sensor 54_{A} is operable to measure at least one electrical parameter of a portion of the grid, including a power supply line such as each line of the electrical bus 30. In some examples, sensor 54_{A} is operable to measure at least one of an instantaneous voltage (measured in volts), an instantaneous current (measured in amperes), and an instantaneous power. In some examples, the electrical parameter(s) measured by the sensor 54_{A} and analyzed by the control assembly 48 includes real and/or imaginary components. In some examples, sensor 54_{B} is a speed sensor operable to detect a rotational speed of the output shaft 40. It should be appreciated that other sensors can be coupled to the sensor interface 52 for detecting various characteristics of the main grid 22 and/or the microgrid 24, and the individual components thereof.

Under some conditions a grid fault or instantaneous change in the electrical grid 20 can occur, such as at location 56, which may adversely affect normal operations of the main grid 22 and/or the microgrid 24. In some instances, a grid fault at location 56 results in the generator assembly 36 continuing to provide power to at least one of the external loads 28, such as external loads 28_{A}. This condition may be referred to as “islanding” or an “islanding condition.” In some operating environments, the microgrid 24 must disconnect from the main grid 22 within a predetermined period of time during islanding conditions. For instance, Institute of Electrical and Electronics Engineers (IEEE) 1547 “Standard for Interconnecting Distributed Resources with Electric Power Systems” specifies that a microgrid shall disconnect from a main grid within approximately two seconds to reduce the likelihood that power is provided to external loads while a main grid is being serviced or repaired. This requirement exists even under conditions where a quantity of power provided to the electrical bus is substantially equal to a quantity of power consumed by components electrically coupled to an electrical bus, which is typically referred to as a non-detect zone (NDZ). Said differently, an NDZ state or condition occurs when power consumption and generation are approximately balanced at a location of the electrical grid 20 such that power flow at the point of fault 56, just before a fault occurs, is very small or approximately zero. A grid fault, such as at location 56, can result in an increase in impedance of the main grid 22 as select portions of the main grid 22, such as external power source 26 and external load 28_{B}, are electrically decoupled from the electrical bus 30. It should be appreciated, however, that the techniques described in this disclosure are not limited to detecting a grid fault during an NDZ state.

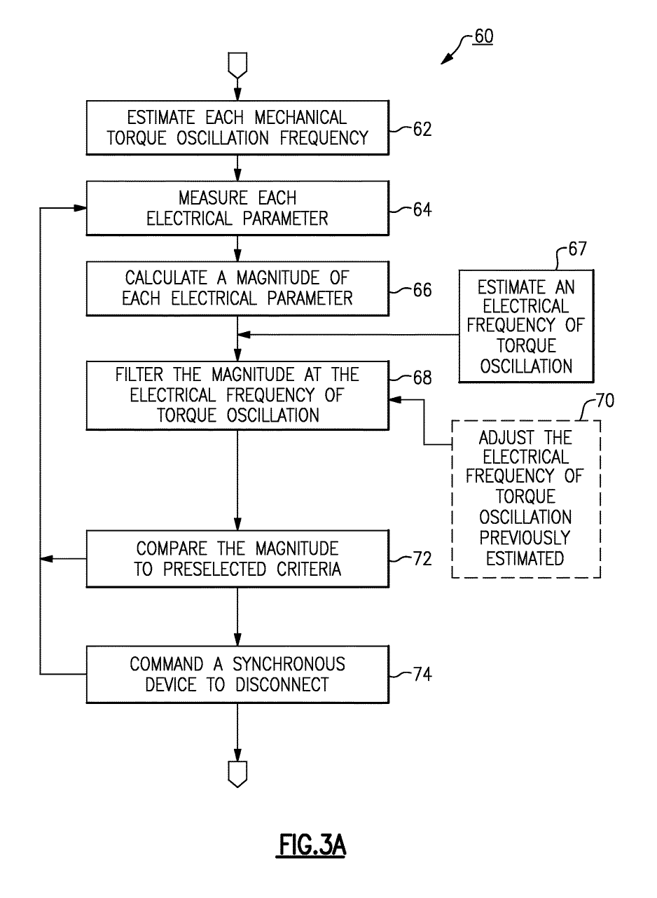

FIG. 3A illustrates a method in a flowchart 60, of detecting a grid condition that may involve or lead to islanding, such as the grid fault at location 56. A grid condition can be a situation where an islanding condition occurs, as previously discussed, and can occur during an NDZ state. At 62 the controller 50 estimates the torque oscillation frequency (ω₁) for at least one mechanical power generation device 38, and in other examples for each mechanical power generation device 38 connected to an electrical bus 30. In one example, the torque oscillation frequency (ω₁) is approximately 235.6 rad/s (37.5 Hz) utilizing parameters for a mechanical power generation device 38 as provided above. In some examples, the rotational speed (ωₙ) of the output shaft 40 is estimated at a steady state operation of the mechanical power generation device 38. In other examples, the torque oscillation frequency (ω₁) may be set or determined and provided to the control assembly 48 at installation.

In some examples, other mechanical generation devices are characterized in a similar manner. For example, a torque oscillation frequency (ω₁) and an associated mechanical torque profile can be estimated for each of the storage devices 46. In other examples, at least one other mechanical generation device and/or one of the storage devices 46 includes a torque oscillation frequency (ω₁) which is different than the torque oscillation frequency (ω₁) of the mechanical power generation device 38. In some examples, the method 60 is adapted to detect a grid condition, fault or reconfiguration based on devices that have different torque oscillation frequencies (ω₁). In another example, a torque oscillation frequency (ω₁) is estimated for a three-phase or single phase static converter coupled to a motor drive.

At 64 the at least one sensor 54_{A} measures instantaneous values of one or more electrical parameters on the electrical bus 30, which can occur while the grid 20 is operating in an NDZ state. The electrical parameter is at least one of an instantaneous voltage, instantaneous current, an instantaneous power and/or impedance on the electrical bus 30 at the location of sensor 54_{A}, for example. In one example, at least one sensor 54_{A} measures the instantaneous values of the a-b-c voltages of the waveforms Phase_{A}, Phase_{B} and Phase_{C} carried on the electrical bus 30, as illustrated in FIG. 3B during normal conditions (left) and an islanding condition (right) (with a grid fault condition (C_{f}) occurring at approximately t=5.35 seconds). In yet other examples, one or more electrical parameters are measured over a period of time, including any electrical parameter provided in this disclosure.

The controller 50 is operable to determine electrical variations relating to mechanical torque oscillations. At 66 the controller 50 calculates a magnitude of the electrical parameter(s). In some operating conditions, the magnitude corresponds to instantaneous variations in mechanical torque of the mechanical generation device 38, such as a voltage magnitude (Vₘ). However, it should be appreciated that in other operating conditions, the electrical variations at an electrical frequency related to the torque oscillation frequency (ω₁) correspond to changes to the configuration of portion(s) of the electrical grid 20, including islanding conditions or other grid faults, even though there is no instantaneous variation in mechanical torque. The magnitude of the electrical parameter can be calculated in various ways, as described in more detail below.

At 67 the controller 50 estimates a frequency of oscillation (f_{T}) relating to a torque oscillation frequency (ω₁) of the mechanical power generation device 38. The frequency of oscillation (f_{T}) depends on a frame in which the electrical parameter(s), such as voltage or current, is analyzed. In some examples, the three-phase voltage waveforms is analyzed in a synchronous reference frame (i.e., the “d-q frame”), where a fundamental component of the voltage on the electrical bus 30 is translated to a direct current (DC) quantity in order to isolate the voltage magnitude corresponding to mechanical torque oscillations of the mechanical power generation device 38. In the synchronous reference frame, the frequency of oscillation (f_{T}) is approximately equal to the torque oscillation frequency (ω₁) of the mechanical power generation device 38.

In another example, the controller 50 determines an “instantaneous envelope” of the electrical parameter(s). In some examples, the controller 50 determines an instantaneous envelope of the three-phase voltage magnitude (Vₘ) using the following equation:

Vₘ=√(Vₐ²+V_{b}²+V_{c}²) Equation 3:

where Vₐ, V_{b} and V_{C} correspond to instantaneous values of the voltages of waveforms Phase_{A}, Phase_{B} and Phase_{C} on the electrical bus 30, for example. The frequency of oscillation (f_{T}) is approximately equal to the torque oscillation frequency (ω₁) in the “instantaneous envelope” technique. The torque oscillations are also reflected at multiples of frequency of oscillation (f_{T}).

In some examples, the method 60 includes estimating or determining any harmonics of the frequency of oscillation (f_{T}) relating to the mechanical torque oscillations of the mechanical power generation device 38. These harmonics include multiples of the frequency or frequencies of oscillation (f_{T}) and any arithmetic combinations thereof, which relate to the torque oscillation frequency (ω₁) of the mechanical power generation device 38 and the fundamental frequency (f_{f}) of the electrical grid 20. The controller 50 is operable to isolate the harmonics corresponding to the mechanical torque oscillations of the mechanical power generation device 38 from other harmonics typically associated with active power electronics which may be present in the electrical grid 20, such as power convertors and active switching devices. In some examples, the harmonics of the frequency of oscillation (f_{T}) is determined by evaluating the electrical parameter(s) with a Fourier transform such as the Fast Fourier Transform (FFT). Considering the harmonics of the frequency of oscillation (f_{T}) relating to the mechanical torque oscillations of the mechanical power generation device 38 can provide additional accuracy in determining whether the electrical variations are related to a grid fault rather than some other condition.

At 68 the controller 50 filters the magnitude at the predetermined frequency or frequencies of oscillation (f_{T}). The predetermined frequency of oscillation (f_{T}) relates to the torque oscillation frequency (ω₁) of the mechanical power generation device 38, as previously discussed. The active power electronics may also produce electrical variations such as voltage oscillations due to operating characteristics of those devices, and not due to any mechanical behavior impinging on the electrical signal communicated by the electrical bus 30. Filtering the electrical parameter(s) at the frequency of oscillation (f_{T}) isolates the electrical variations related to the torque oscillation frequency (ω₁) of the mechanical power generation device 38 from which an islanding condition can be inferred.

Various techniques for filtering the magnitude of the electrical parameter(s) are contemplated. In one example utilizing either of the synchronous reference frame or instantaneous envelope approaches discussed above, the controller 50 implements a band pass filter to filter out frequencies other than the desired frequency or frequencies of oscillation (f_{T}). The band pass filter is implemented to account for variations in the frequency of oscillation (f_{T}) due to variations in the fundamental frequency (f_{f}), such that a range of frequencies including the frequency of oscillation (f_{T}) is observed. Under this approach, a nearly sinusoidal signal having a frequency approximately equal to the mechanical torque oscillation frequency (ω₁) of the mechanical power generation device 38 is provided as an output of the band pass filter.

In another example, utilizing either of the synchronous reference frame or instantaneous envelope approaches discussed above, the controller 50 rectifies an absolute value of the AC signal carried on the electrical bus 30. Thereafter, the controller 50 implements a low pass filter to provide a constant value proportional to a magnitude of the mechanical torque oscillations exhibited by the mechanical power generation device 38.

Other techniques for filtering each electrical parameter are contemplated, including utilizing various Fourier transforms such as Discrete Fourier Transform (DFT) at a frequency of interest. However, DFT typically requires tracking variations in the fundamental frequency (f_{f}) corresponding to variations in the rotational speed (ωₙ) of the output shaft 40, in order to identify the frequency of oscillation (f_{T}). In some examples, any combination of filtering techniques are utilized, including low-pass filters, high-pass filters, band-pass filters, and any combination thereof, such as cascading two or more band-pass filters, to isolate each frequency of interest.

In some examples, the method 60 includes adjusting the predetermined frequency of oscillation (f_{T}) at 70 to isolate each frequency of interest based on sensing a change in rotational speed (ωₙ) of the output shaft 40, which corresponds to a different torque oscillation frequency (ω₁) than estimated at 62. The rotational speed of the output shaft 40 is monitored over a period of time during the operation of the mechanical power generation device 38. In one example, the rotational speed of the output shaft 40 is directly measured, such as by sensor 54_{B}. In another example, the rotational speed of the output shaft 40 is estimated via the fundamental frequency of the electrical parameter (e.g., voltage magnitude).

In some examples, the controller 50 continuously adjusts or refines the estimated frequency of oscillation (f_{T}) over a period of time, although measuring each electrical parameter at 64 occurs instantaneously such as within a single cycle of each electrical parameter. A measurement of RPMs of the output shaft 40 typically occurs at a slower rate than the mechanical torque oscillations exhibited by the mechanical power generation device 38. Thus, in some operating scenarios the controller 50 determines that a grid fault has occurred prior to the filtering algorithm being adjusted based on observing the rotational speed of the output shaft 40. Under certain islanding conditions, the rotational speed of the output shaft 40 may not change; however, the islanding condition can still be detecting utilizing the techniques of this disclosure.

At 72, the controller 50 compares the electrical parameter(s) corresponding to the mechanical torque oscillation of the mechanical power generation device 38 to preselected criteria such as a predetermined threshold (Tₚ). In this example, the electrical parameter is a voltage magnitude on the electrical bus 30. In some examples, the predetermined threshold (Tₚ) is estimated by evaluating the electrical parameter(s) at one or more frequencies and/or frequency ranges under a connected condition (C_{c}) and under a grid fault condition (C_{f}) by experimentation or simulation, as illustrated by FIG. 3C. In one example, the predetermined threshold (Tₚ) is determined through simulation or experimentation based on observation of an assembly approximating operation the mechanical power generation device 38. In another example, the predetermined threshold (Tₚ) is determined through observation of the mechanical power generation device 38 during actual operating conditions. The predetermined threshold (Tₚ) or other preselected criteria are set or determined and provided to the controller 50 at installation. Each preselected criterion can be set or adjusted depending on the needs of a particular situation.

In other examples, the controller 50 compares a magnitude of the current as the electrical parameter of interest which is carried on the electrical bus 30. The controller 50 determines whether the magnitude of the current at a frequency corresponding to the frequency of oscillation (f_{T}) meets preselected criteria, such as being less than a predetermined threshold (Tₚ).

FIG. 3D illustrates an example where the electrical parameter of interest is voltage at the frequency of oscillation (f_{T}) selected from a range of frequencies in FIG. 3C. The controller 50 filters the instantaneous value of the voltage magnitude (Vₘ) at the frequency of oscillation (f_{T}) and compares each instantaneous voltage magnitude (Vₘ) to a predetermined threshold over a period of time. In this example, FIG. 3D illustrates a first condition or normal condition (left), a grid fault condition (C_{f}) occurring at approximately t=5.35 seconds, and a second condition or an islanding condition (right) of the electrical grid 20. A voltage magnitude (Vₘ) greater than the predetermined threshold (Tₚ) indicates an increase in impedance of the main grid 22, caused by a grid fault condition (C_{f}) at location 56, for example.

The increased impedance of the main grid 22 causes electrical variations or oscillations on the electrical bus 30 measured at sensor 54A to be at greater magnitudes than if the main grid 22 was connected to the electrical bus 30 under normal conditions. These electrical variations or oscillations are measured at the frequency of oscillation (f_{T}) or multiples thereof utilizing any of the techniques of this description.

Through experimentation, a voltage magnitude (Vₘ) related to mechanical torque oscillations of a mechanical generation device based on an internal combustion engine increased by approximately a factor of ten due to a simulated grid fault, as compared to a voltage magnitude (Vₘ) due to mechanical torque oscillations occurring under normal operating conditions in which a grid fault is not present. It should be appreciated that under some conditions, a magnitude of the mechanical torque oscillations does not change even though a magnitude of the electrical parameters changes. This condition can occur, for example, because the mechanical torque oscillations are significantly reflected into voltage when the grid impedance is high, even if the magnitude of the torque oscillations does not change when a grid condition occurs. In other conditions, a magnitude of the mechanical torque oscillations does change in response to an islanding condition. Under either condition, variation in the electrical parameter(s) caused by a grid fault can be detected at the frequency of oscillation (f_{T}) or multiples thereof.

At 74, if the controller 50 determines that the magnitude meets the preselected criteria, then the controller 50 commands at least the synchronous device 32 to disconnect the microgrid 24 and/or the generator assembly 36 from the main grid 22. Once the synchronous device 32 opens the connection between the electrical bus 30 and the external loads 28, the generator assembly 36 no longer operates in an islanding condition and may provide power to the microgrid 24 only. In this state, the external loads 28 and devices comprising the microgrid 24, including the generator assembly 36, are protected from anomalies caused by the grid fault. In some examples, the control assembly 48 is configured to communicate the detection of a grid condition to the generator assembly 36 to change a mode of operation, since a frequency and voltage of the generator assembly 36 typically follows frequency and voltage on the electrical grid 20. In other examples, the control assembly 48 communicates or broadcasts the detection of a grid condition to various equipment or devices associated with the electrical grid 20, such as one of the power storage devices 46 or another generator in the microgrid 24, for example.

The controller 50 typically includes a processor, a memory and an interface. The processor may, for example only, be any type of known microprocessor having desired performance characteristics. The memory may, for example only, includes UVPROM, EEPROM, FLASH, RAM, ROM, DVD, CD, a hard drive, or other computer readable medium which may store data and the method 60 for operation of the controller 50 of this description. The interface facilitates communication with the other systems or components comprising the electrical grid 20. In some examples, the controller 50 may be a portion of the generator assembly 36, another system, or a stand-alone system.

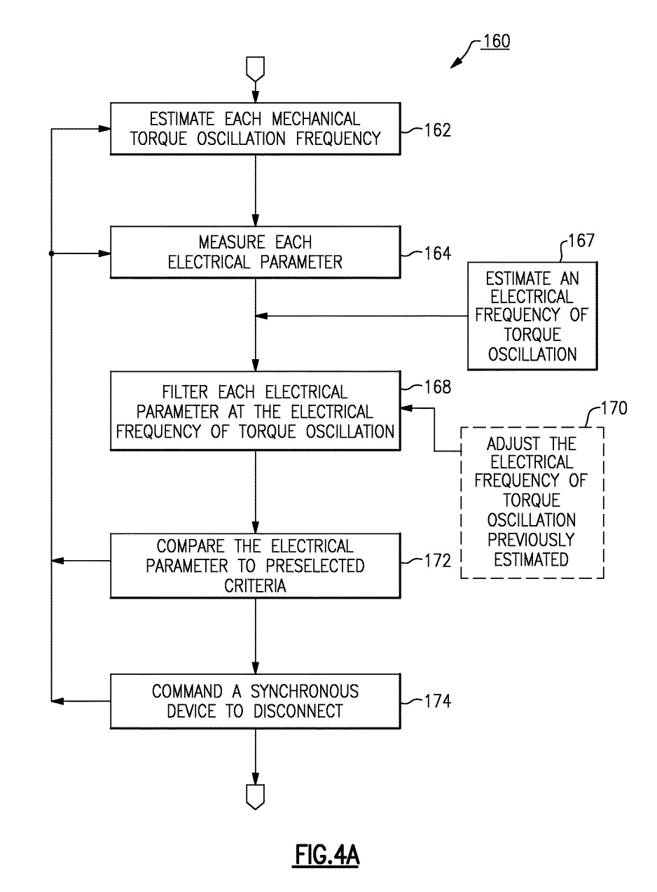

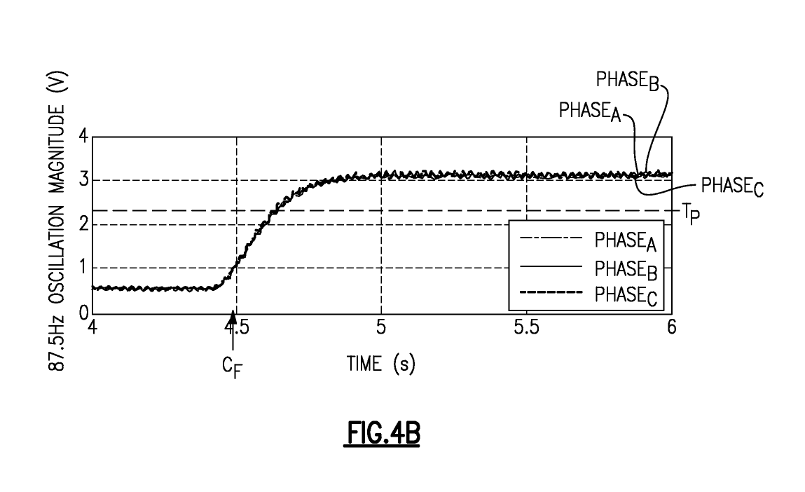

FIG. 4A illustrates a second embodiment of a method in a flowchart 160 of detecting a grid condition by directly analyzing the a-b-c waveforms on a portion of the grid such as the electrical bus 30. The torque oscillation frequency (ω₁) for each mechanical power generation device 38 is estimated at 162, and each electrical parameter is measured at 164 utilizing any of the techniques of this description.

At 167, the controller 50 estimates a frequency of oscillation (f_{T}) relating to a torque oscillation frequency (ω₁) of the mechanical power generation device 38. As previously mentioned, the frequency of oscillation (f_{T}) depends on a frame in which the electrical parameter(s), such as voltage or current, is analyzed. In this embodiment, the three-phase voltage waveforms on a portion of the grid, such as a three-phase power supply line, are analyzed in a stationary reference frame (i.e., the “a-b-c frame” or “α-β frame”). In the stationary reference frame, where voltage and current are sinusoidal with the fundamental frequency (f_{f}) (e.g., approximately 50 Hz or 60 Hz during steady state conditions), the mechanical torque oscillations of the mechanical power generation device 38 will be reflected on voltage or current at frequencies ((ω₁/2π)-f_{f}) and ((ω₁/2π)+f_{f}) and harmonics of those frequencies. The electrical variations corresponding to mechanical torque oscillations of the mechanical power generation device 38 can be observed at each of these frequencies.

At 168, the control assembly 48 filters at least one electrical parameter. The mechanical torque oscillations of the mechanical power generation device 38 are reflected at the frequency of oscillation (f_{T}) on either a positive sequence or a negative sequence of an electrical parameter of the electrical bus 30, such as voltage or current, and in some examples are determined using the stationary reference frame technique previously described. For example, the positive sequence of voltage is 87.5 Hz and the negative sequence of voltage is 12.5 Hz where the torque oscillation frequency (ω₁) is 37.5 Hz and the fundamental frequency (f_{f}) is 50 Hz. Each frequency of oscillation (f_{T}) is filtered at the positive sequence and/or the negative sequence.

At 172, the controller 50 compares each electrical parameter(s), such as the voltage magnitude (Vₘ) corresponding to each of the a-b-c waveforms on the electrical bus 30, to at least one predetermined criterion such as a predetermined threshold (Tₚ). The example controller 150 determines that a grid condition has occurred once any of the voltage magnitude (Vₘ) or other electrical parameter(s) of the a-b-c waveforms at the frequency of oscillation (f_{T}) exceed the predetermined threshold in the case of the positive sequence of the waveform, as illustrated in FIG. 4B, or the negative sequence of the waveform. At 174 the control assembly 148 commands at least the synchronous device 32 to disconnect the microgrid 24 and/or the generator assembly 36 (including the mechanical power generation device 38 and/or the electrical generator 42) from the main grid 22 if a grid condition is detected.

Even though voltage is provided as an example electrical parameter in this description, it should be appreciated that current, power, grid impedance (measured in ohms) and/or other electrical characteristics can be considered in executing any of the methods 60, 160 disclosed herein. In other examples, the electrical parameter is at least one of an instantaneous voltage, an instantaneous current, an instantaneous power and an instantaneous impedance on a portion of the power grid. Other types of mechanical oscillations exhibited by power generation equipment, in addition to an internal combustion engine, are also contemplated in the execution of the methods 60, 160 disclosed herein, including wind turbines, load equipment such as HVAC units, and also combined-heat-power (CHP) equipment, and any of the power storage devices discussed in this disclosure, for example. Also, even though the methods 60, 160 are described in terms of the controller 50, it should be appreciated that another device such as a stand-alone device can be programmed to execute any of the techniques described herein.

Although the different examples have a specific component shown in the illustrations, embodiments of this disclosure are not limited to those particular combinations. It is possible to use some of the components or features from one of the examples in combination with features or components from another one of the examples. It should also be understood that any particular quantities disclosed in the examples herein are provided for illustrative purposes only.

Furthermore, the foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

We claim:

1. An assembly for detecting a grid condition, comprising:
at least one sensor operable to detect an electrical parameter of a portion of a power grid; and
a controller that receives information from the at least one sensor, determines an electrical variation of the electrical parameter based on the information, the electrical variation relating to a mechanical torque oscillation of a power generation device, and determines that the power generation device should be disconnected from the power grid if the electrical variation meets a preselected criterion.

2. The assembly as recited in claim 1, wherein the power generation device is one of an internal combustion engine, a turbine, and a heating, ventilation and air condition (HVAC) system.

3. The assembly as recited in claim 2, wherein:
the power generation device is an internal combustion engine;
the electrical variation occurs at an electrical frequency relating to a mechanical torque oscillation frequency; and
the mechanical torque oscillation frequency is based on at least one of a piston quantity and a rotational speed of the internal combustion engine.

4. The assembly as recited in claim 1, wherein the electrical parameter is at least one of an instantaneous voltage, an instantaneous current, an instantaneous power and an instantaneous impedance on the portion of the power grid.

5. The assembly as recited in claim 1, wherein the electrical variation corresponds to an instantaneous change in mechanical torque produced by the power generation device.

6. The assembly as recited in claim 1, wherein the electrical variation relates to an instantaneous change in configuration of at least a portion of the power grid.

7. The assembly as recited in claim 1, wherein the preselected criterion corresponds to a magnitude of the electrical parameter.

8. A generator assembly, comprising:
a mechanical power generation device having an output shaft;
an electrical generator coupled to the output shaft, the electrical generator having output terminals configured to couple the electrical generator to a portion of a power grid; and
a controller that determines an electrical variation in an electrical parameter of the portion of the power grid relating to a mechanical torque oscillation of the mechanical power generation device at the output shaft, and determines that at least one of the mechanical power generation device and the electrical generator should be disconnected from the portion of the power grid in response to the electrical variation.

9. The generator assembly as recited in claim 8, wherein the controller is operable to change at least one of the mechanical power generation device and the electrical generator from a first operating state to a second operating state in response to the electrical variation.

10. The generator assembly as recited in claim 8, wherein:
the mechanical power generation device is an internal combustion engine;
the electrical variation occurs at an electrical frequency relating to a mechanical torque oscillation frequency; and
the mechanical torque oscillation frequency is based on at least one of a piston quantity and a rotational speed of the internal combustion engine.

11. The generator assembly as recited in claim 8, wherein:
the mechanical power generation device is a turbine;
the electrical variation occurs at an electrical frequency relating to a mechanical torque oscillation frequency; and
the mechanical torque oscillation frequency is based on a quantity of rotor blades of the turbine and a rotational speed of the turbine.

12. The generator assembly as recited in claim 8, wherein the controller is operable to filter the electrical parameter based on a present rotational speed of the output shaft.

13. The generator assembly as recited in claim 8, wherein the electrical variation corresponds to an impedance of the power grid.

14. The generator assembly as recited in claim 8, wherein the portion of the power grid is a microgrid and a main grid, and the controller is operable to determine that the microgrid should be disconnected from the main grid in response to the electrical variation.

15. A method of detecting a grid event, comprising:
determining that an electrical variation of a portion of a power grid meets a preselected criterion, the electrical variation relating to a mechanical torque oscillation of a power generation device; and
disconnecting the power generation device from the portion of the power grid if the electrical variation meets the preselected criterion.

16. The method as recited in claim 15, comprising filtering the electrical variation at an electrical frequency relating to a mechanical torque oscillation frequency of the power generation device, the mechanical torque oscillation occurring at the mechanical torque oscillation frequency.

17. The method as recited in claim 16, wherein the power generation device is an internal combustion engine coupled to an electrical generator via an output shaft, and the mechanical torque oscillation frequency is estimated based on at least one of a piston quantity and a rotational speed of an output shaft of the internal combustion engine.

18. The method as recited in claim 16, wherein the electrical frequency is a first frequency of oscillation and a second frequency of oscillation, the second frequency of oscillation relating to a mechanical torque oscillation of a second power generation device, the first frequency of oscillation and the second frequency of oscillation being separate and distinct.

19. The method as recited in claim 15, wherein the electrical variation corresponds to an instantaneous change in mechanical torque produced by the power generation device.

20. The method as recited in claim 15, wherein the electrical parameter is at least one of an instantaneous voltage, an instantaneous current, an instantaneous power, and an instantaneous impedance on the portion of the power grid.
